(19) United States
(12) Patent Application Publication
(10) Pub. No.: US 2010/0035036 A1
(43) Pub. Date: Feb. 11, 2010

(54) Durable antireflective multispectral infrared coatings

(76) Inventors: John S. McCloy, Tucson, AZ (US); Ralph Korenstein, Framingham, MA (US); Peter E. Cremin, Chelsea, MA (US); Randal W. Rustison, Andover, MA (US)

Correspondence Address: Renner, Otto, Boisselle & Sklar, LLP (Raytheon), 1621 Euclid Avenue - 19th Floor, Cleveland, OH, 44115, US

(21) Appl. No.: 12/228,106

(22) Filed: Aug. 8, 2008

(51) Int. Cl. F21V 9/04; B32B 5/00; C01B 7/19; C23C 14/35; C01F 17/00; C23C 14/34

(52) U.S. Cl. 428/220; 428/336; 423/462; 423/263; 204/192.1; 252/587; 204/192.26

(57) ABSTRACT

Durable antireflective multispectral infrared coatings comprising at least one layer of a metal oxyfluoride are provided.

### BACKGROUND ART

The present application relates generally to antireflective coatings.

Multispectral-ZnS (MS-ZnS) or other high refractive index materials with the necessary wideband transparency for multispectral windows require antireflective (AR) thin film coatings. AR designs typically consist of thin alternating layers of low and high refractive index materials. As used herein, the term “multispectral ZnS” refers to hot isostatic pressed ZnS.

It is desirable to have coatings with as low a refractive index as possible to minimize reflection and maximize the high transmission bandwidth at short IR wavelengths (SWIR, about 1 μm), as emitted, for example by a Nd:YAG laser (1.06 μm). The coatings should also have a high degree of transparency at SWIR, at mid IR wavelengths (MWIR) and at long IR wavelengths (LWIR). For external elements such as IR domes, coatings should be durable to withstand handling and rain and sand erosion. In the past, it was not possible to achieve both durability and low refractive index at the same time in a coating material.

Specifically, AR coatings in the SWIR require materials with index of refraction less than 1.8. There are few good material choices for producing durable AR coatings in the SWIR. Fluorine incorporated in metal oxides has been reported as a means of reducing the index of refraction of some metal oxides; see, e.g., Zheng et al, Applied Optics, Vol. 32, pp. 6303-6309 (1993). For example, the index of refraction of CeOₓF_{y} films was reduced from 2.32 for CeO₂ to 1.62 with the addition of fluorine.

RF (Radio frequency) magnetron sputtered DAR (Durable Anti-Reflective) oxide coatings are known for ZnS domes when only long IR wavelengths (LWIR, 8 to 12 μm) is required; see, e.g., R. Korenstein et al, “Optical Properties of Durable Oxide Coatings for Infrared Applications”, Proceedings of SPIE, Vol. 5078, pp. 169-178 (2003) and Lee M. Goldman et al, “High durability infrared transparent coatings”, SPIE, Vol. 2286, pp. 316-324 (1994). These materials have too high a refractive index to be effective for applications requiring short wave transmission also, as peaks and troughs of transmission due to constructive and destructive interference in the coating are too sensitive to coating thickness and angle of incidence.

Fluorides are often employed for the low index layer, but are usually deposited by evaporation, which leads to non-durable layers.

### DISCLOSURE OF INVENTION

Durable antireflective multispectral infrared coatings comprising at least one layer of a metal oxyfluoride are provided.

### BRIEF DESCRIPTION OF THE DRAWINGS

FIG. 1 is a perspective view of a missile, showing an IR dome.

FIG. 2, on coordinates of transmittance T (%) and wavelength (μm), is a plot showing the effect of adding fluorine to a ZrO₂ coating on the spectral response.

FIG. 3, on coordinates of transmittance T (%) and wavelength (μm), is a plot showing the effect of adding fluorine to a ZrO₂ coating on the UV cut-on.

FIG. 4, on coordinates of hardness (Kg/mm²) and load (gms), depicts the hardness of Zr—O—F coatings.

### BEST MODES FOR CARRYING OUT THE INVENTION

In accordance with the teachings herein, lower refractive index coatings, while still maintaining durability, are achieved. This is accomplished by performing reactive magnetron sputter deposition of metal oxides with a fluorine-containing gas or metals with a gas mixture of oxygen and fluorine. The latter is more likely to have broad applicability due to the flexibility of oxygen to fluorine ratios possible using reactive sputter deposition. These sputter-deposited oxyfluoride coatings have increased durability over fluoride coatings and lower refractive index than oxide coatings. This makes the optical coating design less sensitive to errors in thickness over the part and changes in incident angle.

As used herein, the term “durability” means relative resistance to erosion by sand and/or rain. One measure of durability is hardness.

As used herein, the term “short wavelength IR” means infrared radiation in the vicinity of about 1 μm (0.7 to 3.0 μm).

Reactive RF magnetron sputter deposition of zirconium oxyfluoride appears to be novel. The preparation of cerium oxyfluoride by reactive RF sputter deposition has been reported (see, e.g., Zheng et al, supra). However, this material was not found to be more durable than the substrates when parts were made for the current work described here. Consequently, it could not be applied to the use disclosed herein, namely, durable AR coatings for IR domes. Tailoring of the refractive index and durability can be accomplished by the relative rates of oxide or metal target sputtering, fluorine-containing gas injection, and oxygen injection. This method also allows durable AR coatings to be produced with significantly more transmission in the ultraviolet (UV), due to the fluorine content.

The oxyfluoride compositions are suitably employed as durable coatings on broadband or multimode IR windows, domes, and other elements employed in transmissive applications ranging from near-IR (SWIR) to visible to near-UV, depending on the transparency of the substrate.

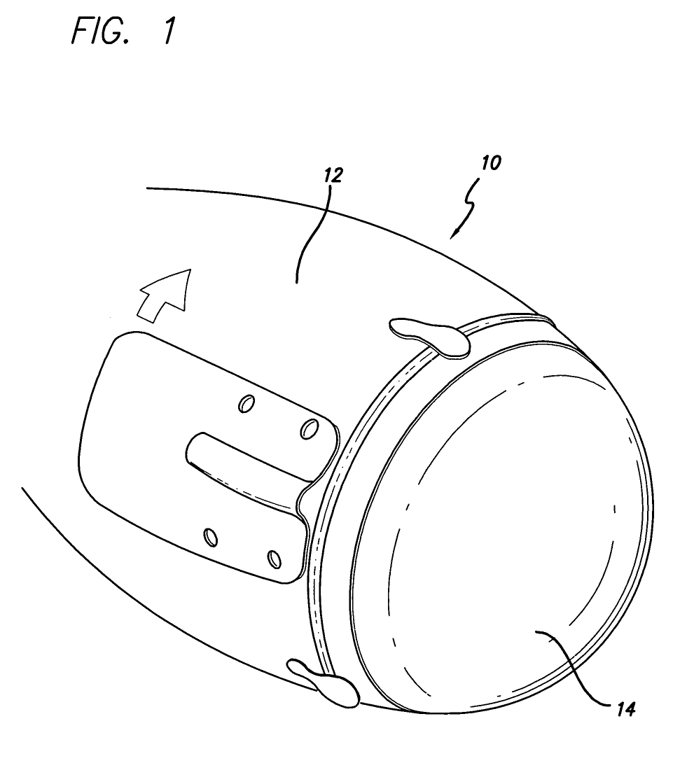

FIG. 1 depicts an example of an IR dome. A missile 10 is depicted, comprising a missile body 12 and an IR dome 14. Other transparent windows may also be suitably coated with the durable antireflective multispectral infrared coating of the invention. The material comprising the IR dome 14 is typically ZnS, ZnSe, Ge, Si, GaAs, GaP, or various chalcogenide glasses.

The oxyfluoride compositions disclosed herein may be employed as single layer AR coatings in some embodiments. In other embodiments, the oxyfluoride coatings may be used in multilayer AR coatings, wherein the oxyfluoride coating is used as the low refractive index coating.

As a single AR coating, the oxyfluoride compositions may have a thickness in the range of about 0.5 to 3 μm in some embodiments. In other embodiments, the thickness may range from about 1 to 2 μm.

Other oxyfluoride compositions, in addition to zirconium oxyfluoride, include the oxyfluorides of yttrium, titanium, hafnium, aluminum, and zinc.

In fabricating an IR dome, the fluorine content of the metal oxyfluoride may be continuously varied or graded to provide at least one of optimum optical performance and optimum mechanical performance. Such variation or grading is readily within the ability of one skilled in this art to carry out.

### EXAMPLES

Thin film coatings were deposited onto both UV-grade fused silica and MS-ZnS substrates by reactive RF magnetron sputtering of Ce and Zr (10% Y) targets using argon/oxygen mixtures. The fluorine source was CF₄. The typical deposition pressure was 5 mTorr and deposition times varied between 1 and 4.5 hours. The RF magnetron sputtering apparatus consisted of a stainless steel chamber that was pumped by a turbo-molecular pump capable of reaching a base pressure of 1×10⁻⁶ torr. Sputtering was done from US Inc. magnetron guns operating at 13.5 MHz. Films of Ce and Zr oxyfluorides were prepared with different F content by sputtering metal targets in a gas with various amounts of CF₄ added to a mixture of Ar and O₂. Specifically, the Ar and O₂ flow rates were set at between 18 and 28 cm³/min at standard temperature (SCCM), while the CF₄ flow rate was between 0 and 9 cm³/min. Hence, the CF₄ concentration varied between 0% and about 30%. The resulting films were in the range of about 1 to 2 μm thick.

The effect of fluorine on the deposition rate of the CeO₂—CF₄ system was to increase the deposition rate with increasing fluorine content. A similar increase in deposition rate with increasing CF₄ was observed in the ZrO₂—CF₄.

Thin films of both CeOₓF_{y} and ZrOₓF_{y} were deposited on fused silica substrates to eliminate any substrate effects. In the cerium-based case, pronounced interference peaks in the CeO₂ film became less pronounced with the presence of fluorine. Further, the UV cut-on shifted towards shorter wavelengths with the presence of fluorine. This is indicative of a continuing decrease in the refractive index with increasing F content.

In the zirconium-based case, essentially the same effects were observed. Again, the magnitude of the interference peaks was observed to decrease and the UV-cut-on shifted to lower wavelengths with the addition of CF₄ to the plasma.

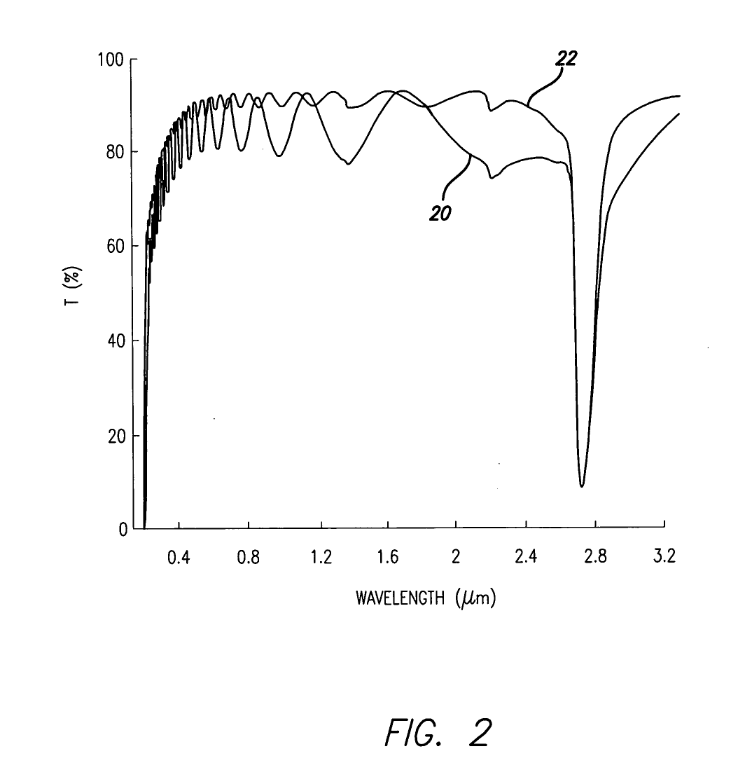

FIG. 2 shows the effect on transmittance of adding F to ZrO₂ coating, where Curve 20 is ZrO₂ with no CF₄ (coating thickness=1.1 μm) and Curve 22 is ZrO₂+30% CF₄ (coating thickness=2.26 μm). In this context, 30% CF₄ refers to the flow rate of CF₄ in the reaction chamber The peak to valley of fringes was lessened, which means less sensitivity to thickness and angle of incidence. These coatings were deposited on UV-grade fused silica 1.08 mm thick.

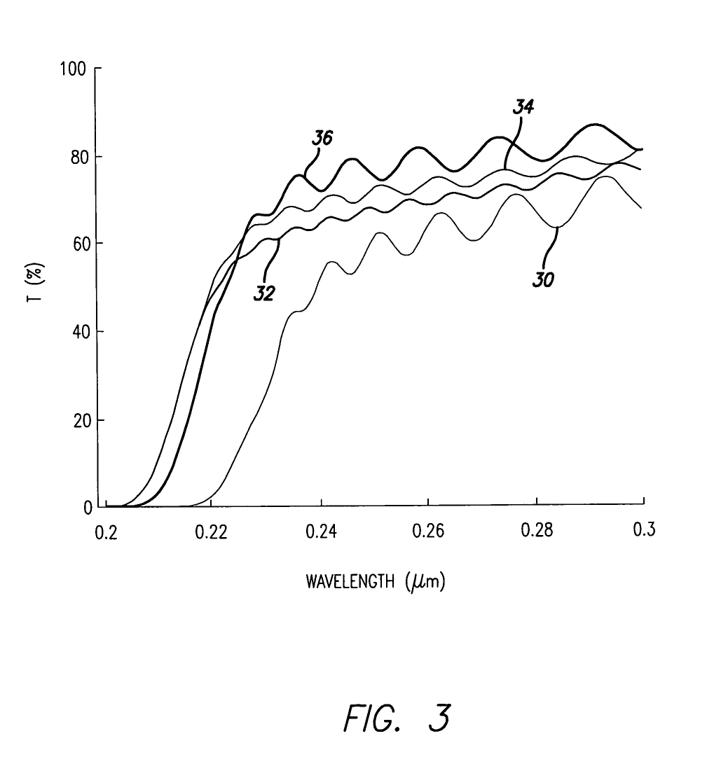

FIG. 3 shows the effect on UV transmittance of adding F to ZrO₂ coating, where Curve 30 is ZrO₂ with no CF₄ (coating thickness=1.1 μm), Curve 32 is ZrO₂+30% CF₄ (thickness=2.26 μm), Curve 34 is ZrO₂+20% CF₄ (coating thickness=1.52 μm), and Curve 36 is ZrO₂+10% CF₄ (coating thickness=1.05 μm). The UV cut-on was observed to shift to shorter wavelengths with increasing CF₄. These coatings were deposited on UV-grade fused silica 1.08 mm thick.

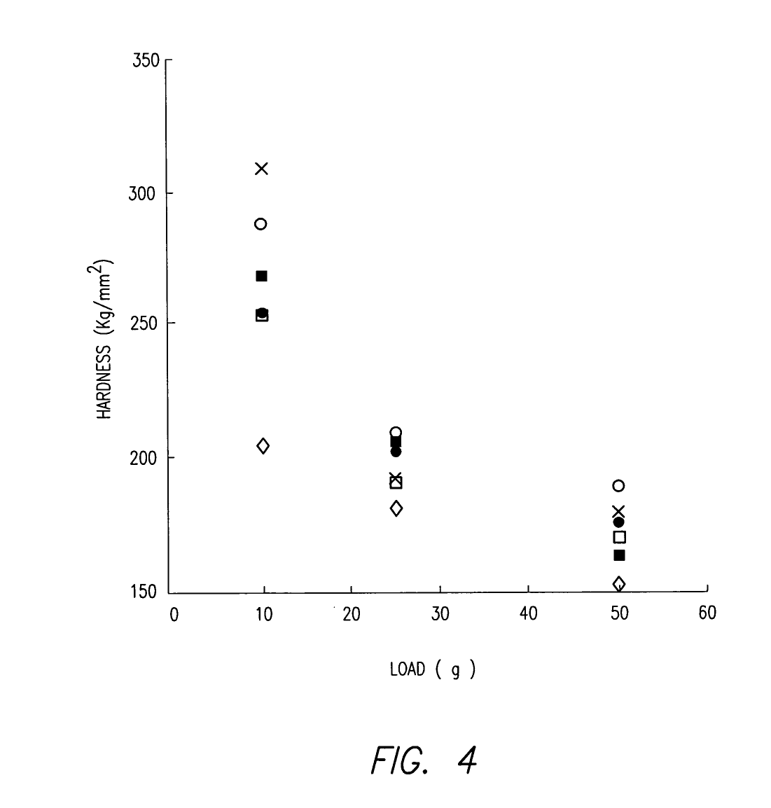

FIG. 4 shows the Knoop hardness of Zr—O—F coatings, where x is ZrO₂ with no CF₄ (coating thickness=1.1 μm), o is ZrO₂ with 30% CF₄ (coating thickness=2.26 μm), is ZrO₂ with 20% CF₄ (coating thickness=1.52 μm), ▪ is ZrO₂ with 10% CF₄ (coating thickness=1.05 μm), o is a commercial evaporative AR coating for comparison, and ⋄ is uncoated MS-ZnS All coatings are harder than the substrate (MS-ZnS 2.54 mm thick). At 20% and greater fluorination, the Zr—O—F coatings are harder than the baseline evaporated AR coating. In this context, hardness is a proxy for erosion resistance.

It will be appreciated that these compositions were not each optimized for hardness. Those skilled in the art will know how to change the RF magnetron sputter deposition parameters (e.g. the chamber pressure) to optimize the coating density.

1. A durable antireflective multispectral infrared coating comprising at least one layer of a metal oxyfluoride.

2. The coating of claim 1 comprising at least one layer of a reactive RF-sputter deposited metal oxyfluoride.

3. The coating of claim 1 wherein said metal oxyfluoride is selected from the group consisting of yttrium oxyfluoride, titanium oxyfluoride, hafnium oxyfluoride, aluminum oxyfluoride, and zinc oxyfluoride.

4. The coating of claim 1 wherein said metal oxyfluoride is zirconium oxyfluoride.

5. The coating of claim 1 having a thickness in the range of about 0.5 to 3 μm.

6. The coating of claim 5 wherein the thickness is in the range of about 1 to 2 μm.

7. A method for forming a durable antireflective multispectral infrared coating on an IR dome, the method comprising reactive RF-sputter deposition of at least one layer of a metal oxyfluoride on an exterior surface of said dome.

8. The method of claim 7 wherein said metal oxyfluoride is selected from the group consisting of yttrium oxyfluoride, titanium oxyfluoride, hafnium oxyfluoride, aluminum oxyfluoride, and zinc oxyfluoride.

9. The method of claim 7 wherein said metal oxyfluoride is zirconium oxide.

10. The method of claim 7 wherein said coating is formed by reactive RF magnetron sputter deposition.

11. The method of claim 7 wherein said metal oxyfluoride is deposited to a thickness of about 0.5 to 3 μm.

12. The method of claim 11 wherein said metal oxyfluoride is deposited to a thickness of about 1 to 2 μm.

13. The method of claim 7 wherein the fluorine content of said metal oxyfluoride is continuously varied or graded to provide at least one of optimum optical performance and optimum mechanical performance.

14. A short wavelength infrared element having a durable antireflective multispectral infrared coating thereon, said coating comprising at least one layer of a metal oxyfluoride.

15. The element of claim 14 wherein said coating comprises at least one layer of an RF-sputter deposited metal oxyfluoride.

16. The element of claim 14 wherein said metal oxyfluoride is selected from the group consisting of yttrium oxyfluoride, titanium oxyfluoride, hafnium oxyfluoride, aluminum oxyfluoride, and zinc oxyfluoride.

17. The element of claim 14 wherein said metal oxyfluoride is zirconium oxyfluoride.

18. The element of claim 14 wherein said element comprises a material selected from the group consisting of ZnS, ZnSe, Ge, and Si.

19. The element of claim 14 wherein said metal oxyfluoride has a thickness in the range of about 0.5 to 3 μm.

20. The element of claim 19 wherein said thickness is in the range of about 1 to 2 μm.
